(19) United States
(12) Patent Application Publication
(10) Pub. No.: US 2024/0429174 A1
(43) Pub. Date: Dec. 26, 2024

(54) SEMICONDUCTOR PACKAGE

(71) Applicant: SAMSUNG ELECTRONICS CO., LTD., Suwon-si (KR)

(72) Inventors: Jing Cheng LIN, Suwon-si (KR); Kwangbae KIM, Suwon-si (KR); Hyunchul JUNG, Suwon-si (KR); Youngkun JEE, Suwon-si (KR)

(73) Assignee: SAMSUNG ELECTRONICS CO., LTD., Suwon-si (KR)

(21) Appl. No.: 18/750,274

(22) Filed: Jun. 21, 2024

(30) Foreign Application Priority Data
Jun. 22, 2023 (KR) 10-2023-0080676

(51) Int. Cl. H01L 23/538; H01L 23/00; H01L 23/29; H01L 23/31; H01L 25/18; H10B 80/00

(52) U.S. Cl. CPC H01L 23/5386; H01L 23/291; H01L 23/3128; H01L 23/5385; H10B 80/00; H01L 24/16; H01L 24/80; H01L 25/18; H01L 2224/16225; H01L 2224/80895; H01L 2224/80896; H01L 2924/1431

(57) ABSTRACT

A semiconductor package according to an embodiment includes a first semiconductor chip, a second semiconductor chip, a first dielectric film surrounding the first semiconductor chip and the second semiconductor chip; first vias; second vias; a bridge chip; a second dielectric film surrounding the bridge chip and having an upper surface and a lower surface opposite to the upper surface; and a third via, some of the first vias are electrically connected to some of the bridge chip pads, some of the second vias are electrically connected to others of the bridge chip pads, and the passivation layer includes a same material as a material of the first dielectric film.

### CROSS-REFERENCE TO RELATED APPLICATION

This application is based on and claims priority under 35 U.S.C. § 119 to Korean Patent Application No. 10-2023-0080676, filed on Jun. 22, 2023, in the Korean Intellectual Property Office, the disclosure of which is incorporated by reference herein in its entirety.

### BACKGROUND

Embodiments of the present disclosure relate to a semiconductor package, and more particularly, to a semiconductor package having a small thickness and improved reliability.

Recently, in the electronic product market, demand for portable devices is rapidly increasing, and as a result, miniaturization and weight reduction of electronic components mounted on these electronic products are continuously required. In order to reduce the size and weight of electronic components, a semiconductor package mounted therein is required to process high-capacity data while the volume of the semiconductor package is small.

### SUMMARY

Embodiments of the present disclosure provide a semiconductor package having a small thickness in which a first chip and a second chip are connected to a bridge chip through direct bonding, the first chip, the second chip, and the bridge chip are fixed through a first oxide film and a first dielectric film instead of a molding member and a substrate, and thermal characteristics and reliability are enhanced by utilizing a second carrier substrate as a heat dissipation member.

Embodiments of the present disclosure are not limited to solving the above-mentioned problems, and other problems that are solved by embodiments of the present disclosure may be clearly understood by those skilled in the art from the description below.

According to embodiments of the present disclosure, a semiconductor package is provided. The semiconductor package includes: a first semiconductor chip; a second semiconductor chip spaced apart from the first semiconductor chip in a horizontal direction; a first dielectric film surrounding the first semiconductor chip and the second semiconductor chip; first vias extending from a lower surface of the first dielectric film to a lower surface of the first semiconductor chip; second vias extending from the lower surface of the first dielectric film to a lower surface of the second semiconductor chip; a bridge chip on the lower surface of the first dielectric film and electrically connected to each of the first semiconductor chip and the second semiconductor chip, the bridge chip including bridge chip pads and a passivation layer surrounding the bridge chip pads; a second dielectric film surrounding the bridge chip and having an upper surface and a lower surface opposite to the upper surface of the second dielectric film; and third vias extending from the lower surface of the second dielectric film to the upper surface of the second dielectric film, wherein a first set of the first vias is electrically connected to a first set of the bridge chip pads, wherein a first set of the second vias is electrically connected to a second set of the bridge chip pads, and wherein the passivation layer includes a same material as a material of the first dielectric film.

According to embodiments of the present disclosure, a semiconductor package is provided. The semiconductor package includes: a first semiconductor chip; a second semiconductor chip spaced apart from the first semiconductor chip in a horizontal direction; a first dielectric film surrounding the first semiconductor chip and the second semiconductor chip; a carrier substrate that contacts an upper surface of the first semiconductor chip, an upper surface of the second semiconductor chip, and an upper surface of the first dielectric film; first vias extending from a lower surface of the first dielectric film to a lower surface of the first semiconductor chip; second vias extending from the lower surface of the first dielectric film to a lower surface of the second semiconductor chip; a bridge chip on the lower surface of the first dielectric film and electrically connected to each of the first semiconductor chip and the second semiconductor chip, the bridge chip including bridge chip pads and a passivation layer surrounding the bridge chip pads; a second dielectric film surrounding the bridge chip and having an upper surface and a lower surface opposite to the upper surface of the second dielectric film; and third vias extending from the lower surface of the second dielectric film to the upper surface of the second dielectric film, wherein a first set of the first vias is electrically connected to a first set of the bridge chip pads, wherein a first set of the second vias is electrically connected to a second set of the bridge chip pads, and wherein the passivation layer includes a same material as a material of the first dielectric film, the first set of the first vias and the first set of the bridge chip pads include a same material as each other, and the first set of the second vias and the second set of the bridge chip pads include a same material as each other.

According to embodiments of the present disclosure, a semiconductor package is provided. The semiconductor package includes: a first semiconductor chip; a second semiconductor chip spaced apart from the first semiconductor chip in a horizontal direction; a first dielectric film surrounding the first semiconductor chip and the second semiconductor chip; at least one third dielectric film on a upper surface of the first semiconductor chip and an upper surface of the second semiconductor chip; a carrier substrate including a fourth dielectric film that contacts an upper surface of the at least one third dielectric film and an upper surface of the first dielectric film; first vias extending from a lower surface of the first dielectric film to a lower surface of the first semiconductor chip; second vias extending from the lower surface of the first dielectric film to a lower surface of the second semiconductor chip; a bridge chip on the lower surface of the first dielectric film and electrically connected to each of the first semiconductor chip and the second semiconductor chip, the bridge chip including bridge chip pads and a passivation layer surrounding the bridge chip pads; a second dielectric film surrounding the bridge chip and having an upper surface and a lower surface opposite to the upper surface of the second dielectric film; third vias extending from the lower surface of the second dielectric film to the upper surface of the second dielectric film, and a first bump on the lower surface of the second dielectric film and electrically connected to one of the third vias, wherein a first set of the first vias is electrically connected to a first set of the bridge chip pads, wherein a first set of the second vias is electrically connected to a second set of the bridge chip pads, wherein the passivation layer includes a same material as a material of the first dielectric film, the first set of the first vias and the first set of the bridge chip pads include a same material as each other, and the first set of the second vias and the second set of the bridge chip pads include a same material as each other, and wherein lower surfaces of the first set of the first vias and upper surfaces of the first set of the bridge chip pads are in contact with each other, lower surfaces of the first set of the second vias and upper surfaces of the second set of the bridge chip pads are in contact with each other, and each of the first dielectric film and the second dielectric film includes one from among a silicon oxide film and a silicon nitride film.

### BRIEF DESCRIPTION OF DRAWINGS

Embodiments will be more clearly understood from the following detailed description taken in conjunction with the accompanying drawings in which:

FIG. 1 is a schematic cross-sectional view illustrating a semiconductor package according to an embodiment;

FIG. 2 is a schematic bottom view of the semiconductor package of FIG. 1;

FIG. 3 is an enlarged view illustrating coupling of a first chip, a second chip, and a first dielectric film of FIG. 1 to a carrier substrate;

FIG. 4 is a schematic cross-sectional view illustrating a semiconductor package according to an embodiment;

FIG. 5 is a schematic cross-sectional view illustrating a semiconductor package according to an embodiment;

FIG. 6 is a schematic cross-sectional view illustrating a semiconductor package according to an embodiment;

FIGS. 7A to 7M are cross-sectional views illustrating a method of manufacturing a semiconductor package, according to an embodiment.

### DETAILED DESCRIPTION

Hereinafter, non-limiting example embodiments of the present disclosure will be described in detail with reference to the accompanying drawings. Like reference numerals are used for elements that are substantially identical to each other, and the descriptions thereof may not be repeated.

It will be understood that when an element or layer is referred to as being “on,” “connected to,” or “coupled to” another element or layer, it can be directly on, connected to, or coupled to the other element or layer or intervening elements or layers may be present. In contrast, when an element or layer is referred to as being “directly on,” “directly connected to,” or “directly coupled to” another element or layer, there are no intervening elements or layers present.

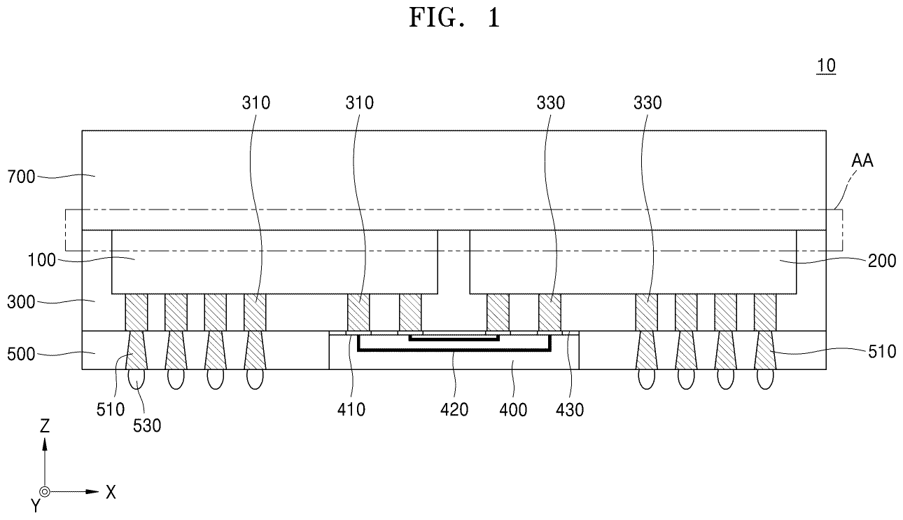

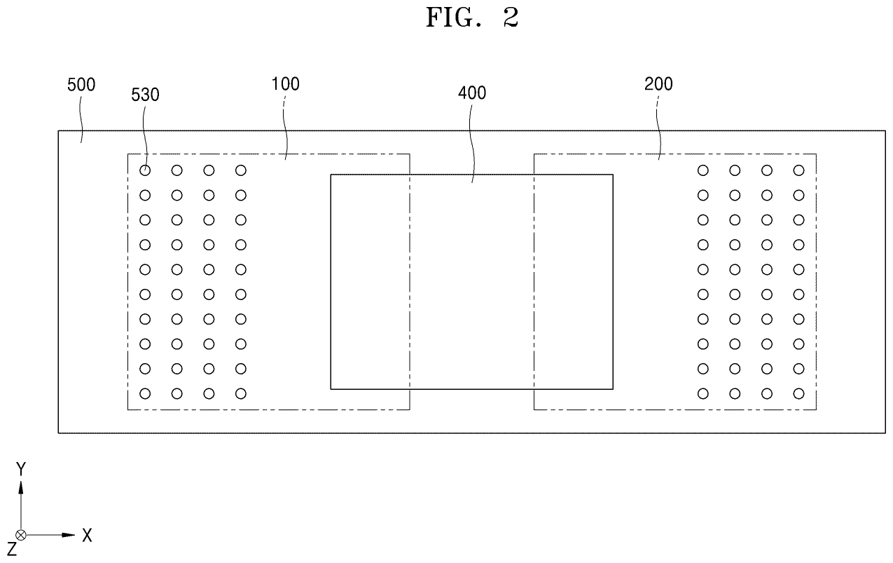

FIG. 1 is a schematic cross-sectional view illustrating a semiconductor package 10 according to an embodiment. FIG. 2 is a schematic bottom view of the semiconductor package 10 of FIG. 1.

Referring to FIGS. 1 and 2, the semiconductor package 10 according to an embodiment includes a first semiconductor chip 100, a second semiconductor chip 200, a first dielectric film 300, a first via 310, a second via 330, a bridge chip 400, a second dielectric film 500, a third via 510, and a second carrier substrate 700.

The first semiconductor chip 100 and the second semiconductor chip 200 may be positioned under the second carrier substrate 700. According to some embodiments, the first semiconductor chip 100 and the second semiconductor chip 200 may be disposed to be in contact with a lower surface of the second carrier substrate 700. At this time, the meaning of being in contact may include direct contact between upper surfaces of the first semiconductor chip 100 and the second semiconductor chip 200, respectively, with the lower surface of the second carrier substrate 700 as well as contacting the upper surfaces of the first semiconductor chip 100 and the second semiconductor chip 200, respectively, with the lower surface of the second carrier substrate 700 by interposing a dielectric film therebetween.

The first semiconductor chip 100 and the second semiconductor chip 200 may be spaced apart from each other in a horizontal direction. The first semiconductor chip 100 and the second semiconductor chip 200 may include memory chips or logic chips. In this case, both the first semiconductor chip 100 and the second semiconductor chip 200 may be the same type of chip or may be different types of chips. For example, both the first semiconductor chip 100 and the second semiconductor chip 200 may be memory chips, or one of the first semiconductor chip 100 and the second semiconductor chip 200 may be a memory chip and the other one may be a logic chip.

The memory chip may be, for example, a volatile memory chip such as dynamic random access memory (DRAM) or static random access memory (SRAM), or a non-volatile memory chip such as phase-change random access memory (PRAM), magnetic random access memory (MRAM), ferroelectric random access memory (FeRAM), or resistive random access memory (RRAM). In addition, the logic chip may be, for example, a microprocessor (e.g., a central processing unit (CPU), a graphics processing unit (GPU), or an application processor (AP)), an analog device, or a digital signal processor.

The first dielectric film 300 may be positioned below the second carrier substrate 700. The first dielectric film 300 may surround the first semiconductor chip 100 and the second semiconductor chip 200. The first dielectric film 300 may surround side surfaces of each of the first semiconductor chip 100 and the second semiconductor chip 200. The first dielectric film 300 includes an upper surface and a lower surface opposite to the upper surface, and the upper surface of the first dielectric film 300 may be disposed to contact the lower surface of the second carrier substrate 700. The first dielectric film 300 may include any one from among silicon nitride and silicon oxide.

In the drawings, an X-axis direction and a Y-axis direction represent directions parallel to the upper or lower surface of the first dielectric film 300, and the X-axis direction and the Y-axis direction may be directions perpendicular to each other. A Z-axis direction may indicate a direction perpendicular to the upper or lower surface of the first dielectric film 300. In other words, the Z-axis direction may be a direction perpendicular to an X-Y plane.

Also, in the drawings, a first horizontal direction, a second horizontal direction, and a vertical direction may be understood as follows. The first horizontal direction may be understood as the X-axis direction, the second horizontal direction may be understood as the Y-axis direction, and the vertical direction may be understood as the Z-axis direction.

According to some embodiments, the upper surface of the first dielectric film 300 may be positioned at substantially the same level in the vertical direction (Z) as the upper surface of the first semiconductor chip 100 and the upper surface of the second semiconductor chip 200. In other words, the upper surface of the first dielectric film 300 may be positioned on substantially the same plane as the upper surface of the first semiconductor chip 100 and the upper surface of the second semiconductor chip 200.

According to some embodiments, the lower surface of the first dielectric film 300 may be at a level in the vertical direction (Z) lower than the lower surface of the first semiconductor chip 100 and the lower surface of the second semiconductor chip 200. In this case, the first dielectric film 300 may cover the lower surfaces of each of the first semiconductor chip 100 and the second semiconductor chip 200 . . . .

The first via 310 may be a through electrode penetrating the first dielectric film 300 from the lower surface of the first dielectric film 300 to the lower surface of the first semiconductor chip 100. The first via 310 may have a shape extending from the lower surface of the first dielectric film 300 toward the lower surface of the first semiconductor chip 100. In some embodiments, the first via 310 may have a pillar shape extending in the vertical direction Z. However, the shape of the first via 310 is not limited thereto. For example, the first via 310 may have a tapered shape in which a horizontal width increases or decreases as the level in the vertical direction Z decreases.

A plurality of the first vias 310 may be provided. Each of the plurality of the first vias 310 may extend from the lower surface of the first semiconductor chip 100 to the lower surface of the first dielectric film 300. Some of the plurality of the first vias 310 may be electrically connected to a plurality of the third vias 510 and other ones of the plurality of the first vias 310 may be electrically connected to the bridge chip 400. In some embodiments, each of the plurality of the first vias 310 connected to the plurality of the third vias 510 may not overlap the bridge chip 400 in the vertical direction Z, and each of the plurality of the first vias 310 connected to the bridge chip 400 may overlap the bridge chip 400 in the vertical direction Z.

According to some embodiments, each of the plurality of the first vias 310 may be connected to each of the plurality of the third vias 510. That is, one first via 310 may be connected to one third via 510. However, embodiments of the present disclosure are not limited thereto. For example, the first via 310 and the third via 510 may be connected at different ratios according to signal configuration.

According to some embodiments, each of the plurality of the first vias 310 connected to the bridge chip 400 may be connected to a plurality of bridge chip pads 410 formed on an upper surface of the bridge chip 400. At least some of the plurality of the first vias 310 may overlap the bridge chip pads 410 in the vertical direction Z.

A plurality of the second vias 330 may be provided. Each of the plurality of the second vias 330 may extend from the lower surface of the second semiconductor chip 200 to the lower surface of the first dielectric film 300. Some of the plurality of the second vias 330 may be electrically connected to a plurality of the third vias 510 and other ones may be electrically connected to the bridge chip 400. In some embodiments, each of the plurality of the second vias 330 connected to the plurality of the third vias 510 may not overlap the bridge chip 400 in the vertical direction Z, and each of the plurality of the second vias 330 connected to the bridge chip 400 may overlap the bridge chip 400 in the vertical direction Z.

According to some embodiments, each of the plurality of the second vias 330 may be connected to each of the plurality of the third vias 510. However, embodiments of the present disclosure are not limited thereto. For example, the second via 330 and the third via 510 may be connected at different ratios according to signal configuration.

According to some embodiments, each of the plurality of the second vias 330 connected to the bridge chip 400 may be connected to a plurality of bridge chip pads 410 formed on the upper surface of the bridge chip 400. At least some of the plurality of the second vias 330 may overlap the bridge chip pads 410 in the vertical direction Z.

At least some of the plurality of the first vias 310 and at least some of the plurality of the third vias 510 may be connected to each other without a separate connecting member (e.g., a metal pillar, a solder bump, etc.), and at least some of the plurality of the second vias 330 and other ones of the plurality of the third vias 510 may also be connected to each other without a separate connecting member.

At least some of the plurality of the first vias 310 and the bridge chip pads 410 may be connected to each other without a separate connection member, and in this case, the at least some of the plurality of the first vias 310 and the bridge chip pads 410 may be connected through direct bonding. The direct bonding may include a dielectric-to-dielectric bonding, a copper-to-copper bonding, and a hybrid bonding in which the dielectric-dielectric bonding and the metal-metal bonding occur together. The direct bonding may be a diffusion bonding in which, after two interfaces including the same material are arranged to face each other, metal atoms or dielectric materials in contact with each other are brought into contact with each other and heated to form an integral body through diffusion.

A lower surface of the first via 310 and an upper surface of at least one of the bridge chip pads 410 may be positioned to face each other, and the lower surface of the first dielectric film 300 surrounding the plurality of the first vias 310 and an upper surface of a passivation layer 430 surrounding the bridge chip pads 410 may face each other. That is, the lower surface of the first via 310 is in contact with at least one of the bridge chip pads 410, and the lower surface of the first dielectric film 300 surrounding the plurality of the first vias 310 may contact the upper surface of the passivation layer 430 surrounding the bridge chip pads 410.

At least some of the plurality of the second vias 330 and the bridge chip pads 410 may be connected to each other without a separate connection member, and the at least some of the plurality of the second vias 330 and the bridge chip pads 410 may be connected through direct bonding.

The bridge chip 400 may be positioned under the first dielectric film 300. The bridge chip 400 may electrically connect the first semiconductor chip 100 to the second semiconductor chip 200. The bridge chip 400 is a chip connecting different types of semiconductor chips, and the different types of chips may include process chips, logic chips, memory chips, and the like. The bridge chip 400 may, for example, perform as a bridge electrically connecting a logic chip and a memory chip and may have a pitch corresponding to a fine pitch of each of the logic chip and the memory chip.

According to some embodiments, the bridge chip 400 may be electrically connected to at least some of the plurality of the first vias 310 and at least some of the plurality of the second vias 330. The bridge chip 400 may include the plurality of bridge chip pads 410, a wiring pattern 420, and the passivation layer 430. The bridge chip pads 410 may be disposed on the upper surface of the bridge chip 400. The upper surface of the bridge chip 400 may be a surface facing the first dielectric film 300. The plurality of bridge chip pads 410 may be spaced apart from each other in the horizontal direction. Among the plurality of bridge chip pads 410, the bridge chip pads 410 connected to the plurality of the first vias 310 may include the same material as the plurality of the first vias 310, and among the plurality of bridge chip pads 410, the bridge chip pads 410 connected to the plurality of the second vias 330 may include the same material as the plurality of the second vias 330.

In this case, the plurality of the first vias 310 and the plurality of the second vias 330 may include the same material but are not limited thereto. For example, the plurality of the first vias 310 and the plurality of the second vias 330 may include different materials.

The passivation layer 430 may surround the bridge chip pads 410. The passivation layer 430 may be positioned on the upper surface of the bridge chip 400. The passivation layer 430 may surround side surfaces of the bridge chip pads 410. An upper surface of each of the bridge chip pads 410 may be exposed upward from the passivation layer 430 in the vertical direction Z.

The passivation layer 430 may include any one from among silicon oxide and silicon nitride. The passivation layer 430 may include the same material as the first dielectric film 300. For example, when the first dielectric film 300 includes silicon oxide, the passivation layer 430 may include silicon oxide.

In some embodiments, each of the bridge chip pads 410 may include a plurality of layers. For example, each of the bridge chip pads 410 may include a copper layer made of copper (Cu), a nickel layer made of nickel (Ni), and a silver layer made of silver (Ag), and the copper layer, the nickel layer, and the silver layer may be stacked one after another in the vertical direction Z.

The wiring pattern 420 may be formed inside the bridge chip 400 and electrically connect different bridge chip pads 410 to each other. According to some embodiments, the wiring pattern 420 may include a bridge circuit. The bridge circuit may have a pitch corresponding to a fine pitch of pads formed on each of different semiconductor chips and may perform as a bridge electrically connecting the semiconductor chips to each other.

For example, the first semiconductor chip 100 may be electrically connected to the bridge chip pads 410 located on the left side of the upper surface of the bridge chip 400 through the plurality of the first vias 310 located on the right side of the lower surface of the first semiconductor chip 100. In addition, the second semiconductor chip 200 may be electrically connected to the bridge chip pads 410 located on the right side of the upper surface of the bridge chip 400 through the plurality of the second vias 330 located on the left side of the lower surface of the second semiconductor chip 200. Because the wiring pattern 420 electrically connects the bridge chip pads 410, the first semiconductor chip 100 and the second semiconductor chip 200 may be electrically connected to each other.

The second dielectric film 500 is positioned below the first dielectric film 300 and may surround the bridge chip 400. According to some embodiments, the second dielectric film 500 may include one from among silicon nitride and silicon oxide. The second dielectric film 500 has an upper surface and a lower surface opposite to the upper surface, and the upper surface of the second dielectric film 500 may be at substantially the same level as the upper surface of the bridge chip 400 (or the upper surface of the bridge chip pads 410) in the vertical direction Z. The lower surface of the second dielectric film 500 may be at substantially the same level as the lower surface of the bridge chip 400 in the vertical direction Z.

The first dielectric film 300 and the second dielectric film 500 may include the same material but are not limited thereto. For example, the first dielectric film 300 and the second dielectric film 500 may include different materials. For example, the first dielectric film 300 may include silicon oxide and the second dielectric film 500 may include silicon nitride.

The plurality of the third vias 510 may extend from the lower surface to the upper surface of the second dielectric film 500. According to some embodiments, each of the plurality of the third vias 510 may have a tapered shape in which a horizontal width increases as the level in the vertical direction Z decreases. However, it is not limited thereto. For example, each of the plurality of the third vias 510 may have a shape in which the horizontal width decreases as the level in the vertical direction Z decreases or may have a column shape in which the horizontal width is constant.

The plurality of third the via 510 may be provided, wherein some of the plurality of the third vias 510 may be connected to at least some of the plurality of the first vias 310 and others of the plurality of the third vias 510 may be connected to at least some of the plurality of the second vias 330. Lower surfaces of the plurality of the third vias 510 may be exposed downward from the second dielectric film 500 in the vertical direction Z. First bumps 530 may be connected to the lower surface of the plurality of the third vias 510. The first bumps 530 may have a pillar structure, a ball structure, or a solder layer.

The second carrier substrate 700 may be disposed on the upper surface of the first semiconductor chip 100, the upper surface of the second semiconductor chip 200, and the upper surface of the first dielectric film 300. The second carrier substrate 700 may include silicon (Si). The carrier substrate may be a substrate for fixing the first semiconductor chip 100 and the second semiconductor chip 200 in a process of manufacturing the semiconductor package 10 and may be a substrate that is removed again during the manufacturing process. However, the second carrier substrate 700 of the semiconductor package 10 according to some embodiments is not removed during the manufacturing process and may function as a part of a final structure of the semiconductor package 10. The second carrier substrate 700 may include silicon (Si). Because a thickness of the second carrier substrate 700 may be freely adjusted in the vertical direction Z through grinding or the like, a thickness of the semiconductor package 10 in the vertical direction Z may be adjusted according to demand or suitable for preventing warpage. In addition, the second carrier substrate 700 may function as a heat dissipation member that discharges heat generated inside the semiconductor package 10 to the outside.

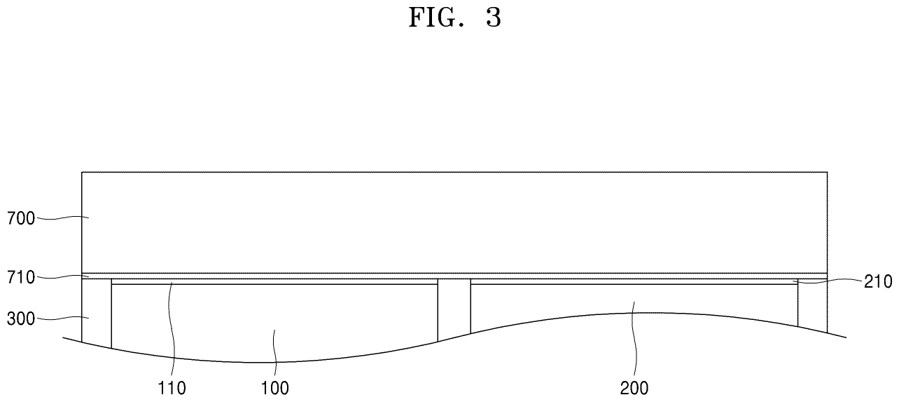

The second carrier substrate 700 may be coupled to the upper surface of the first semiconductor chip 100, the upper surface of the second semiconductor chip 200, and the upper surface of the first dielectric film 300 through direct bonding, which will be described later in detail with reference to FIG. 3.

In the semiconductor package 10 according to some embodiments, because the bridge chip 400 is connected to the first semiconductor chip 100 and the second semiconductor chip 200 through direct bonding, even if the first semiconductor chip 100, the second semiconductor chip 200, and the bridge chip 400 have a fine pitch, they may be easily bonded. In addition, because the bridge chip 400 is mounted on the second dielectric film 500 instead of a conventional substrate, and because the first dielectric film 300 surrounds the first semiconductor chip 100 and the second semiconductor chip 200, it is possible to prevent voids from occurring inside the semiconductor package 10. In addition, because an underfill process may be omitted by the first dielectric film 300 and the second dielectric film 500, the manufacturing process may be simplified and the thickness of the semiconductor package 10 in the vertical direction Z may be formed to be thin.

FIG. 3 is an enlarged view illustrating coupling of the first semiconductor chip 100, the second semiconductor chip 200, and the first dielectric film 300 of FIG. 1 to the second carrier substrate 700.

Referring to FIG. 3, each of the first semiconductor chip 100 and the second semiconductor chip 200 may include third dielectric films 110 and 210. The third dielectric films 110 and 210 may be formed on the upper surfaces of each of the first semiconductor chip 100 and the second semiconductor chip 200. In other words, the upper surface of the first semiconductor chip 100 and the upper surface of the second semiconductor chip 200 may be coated with the third dielectric films 110 and 210. In some embodiments, the third dielectric films 110 and 210 may include the same material as the first dielectric film 300. For example, when the first dielectric film 300 includes silicon oxide, the third dielectric films 110 and 210 may include silicon oxide. Accordingly, the upper surface of the first dielectric film 300, the upper surface of the first semiconductor chip 100, and the upper surface of the second semiconductor chip 200 that contact the lower surface of the second carrier substrate 700 may all include the same material. Here, the upper surface of the first semiconductor chip 100 and the upper surface of the second semiconductor chip 200 may be understood as the upper surfaces of third dielectric films 110 and 210 unless otherwise specified.

A fourth dielectric film 710 may be formed on the lower surface of the second carrier substrate 700. The fourth dielectric film 710 may include the same material as the first dielectric film 300. The lower surface of the second carrier substrate 700 may be coated with the fourth dielectric film 710. The lower surface of the second carrier substrate 700 may contact the upper surface of the first dielectric film 300, the upper surface of the first semiconductor chip 100, and the upper surface of the second semiconductor chip 200. Here, the lower surface of the second carrier substrate 700 may be understood as the fourth dielectric film 710 unless otherwise specified.

The second carrier substrate 700 may be coupled to the first dielectric film 300, the first semiconductor chip 100, and the second semiconductor chip 200 through direct bonding. Because the first dielectric film 300, the upper surface of the first semiconductor chip 100, the upper surface of the second semiconductor chip 200, and the lower surface of the second carrier substrate 700 all include the same material, they may be combined through dielectric-dielectric bonding.

The third dielectric films 110 and 210 may be dielectric films formed by applying a dielectric material on the upper surface of each of the first semiconductor chip 100 and the second semiconductor chip 200, respectively, but are not limited thereto, and may be previously existing dielectric films, such as silicon oxide films formed on a silicon surface.

Similarly, the fourth dielectric film 710 may be a dielectric film formed by coating a dielectric material on the lower surface of the second carrier substrate 700 but may also be a previously existing dielectric film, such as a silicon oxide film formed on a silicon surface.

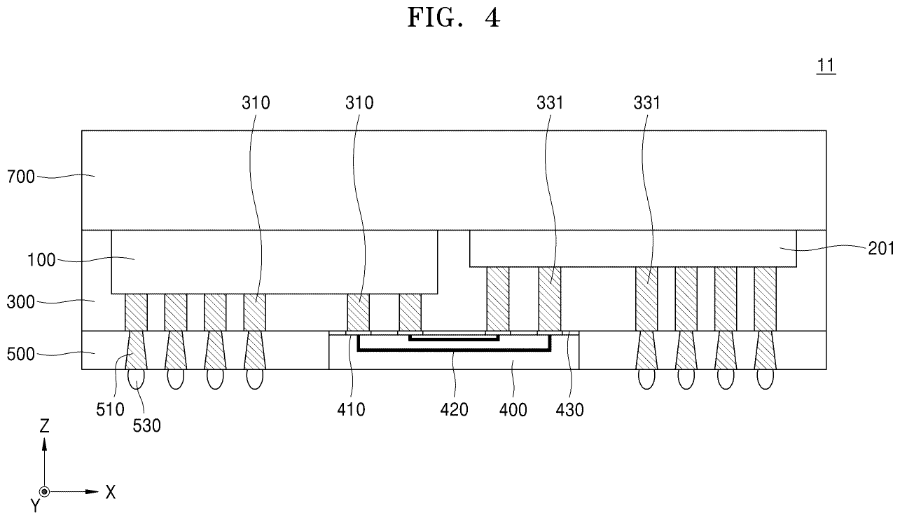

FIG. 4 is a schematic cross-sectional view of a semiconductor package 11 according to an embodiment. Hereinafter, in the description of the semiconductor package 11 of FIG. 4, descriptions identical to descriptions about the semiconductor package 10 given above with reference to FIGS. 1 and 2 may be omitted.

Referring to FIG. 4, the semiconductor package 11 may include a first semiconductor chip 100, a second semiconductor chip 201, a first dielectric film 300, a plurality of first via 310, a plurality of second via 331, a bridge chip 400, a second dielectric film 500, a plurality of third via 510, and a second carrier substrate 700.

According to some embodiments, a thickness of the first semiconductor chip 100 in the vertical direction Z may be greater than a thickness of the second semiconductor chip 201 in the vertical direction Z. When the second carrier substrate 700 has a flat plate shape, because an upper surface of the first semiconductor chip 100 and an upper surface of the second semiconductor chip 201 are in contact with a lower surface of the second carrier substrate 700, the upper surface of the first semiconductor chip 100 and the upper surface of the second semiconductor chip 201 are at the same level in the vertical direction Z to each other, and a lower surface of the first semiconductor chip 100 may be at a level lower than a level of a lower surface of the second semiconductor chip 201 in the vertical direction Z.

A length of each of the plurality of the first vias 310 in the vertical direction Z may be less than a length of each of the plurality of the second vias 331 in the vertical direction Z. According to some embodiments, lower surfaces of the plurality of the first vias 310 and lower surfaces of the plurality of the second vias 331 are at substantially the same level in the vertical direction Z, and upper surfaces of the plurality of the first vias 310 are at a level lower than a level of the upper surfaces of the plurality of the second vias 331 in the vertical direction Z. In some embodiments, a length of the first semiconductor chip 100 in the first horizontal direction X may be less than a length of the second semiconductor chip 201 in the first horizontal direction X. A footprint (e.g., an area when viewed from a top view) of the first semiconductor chip 100 may be less than a footprint of the second semiconductor chip 201.

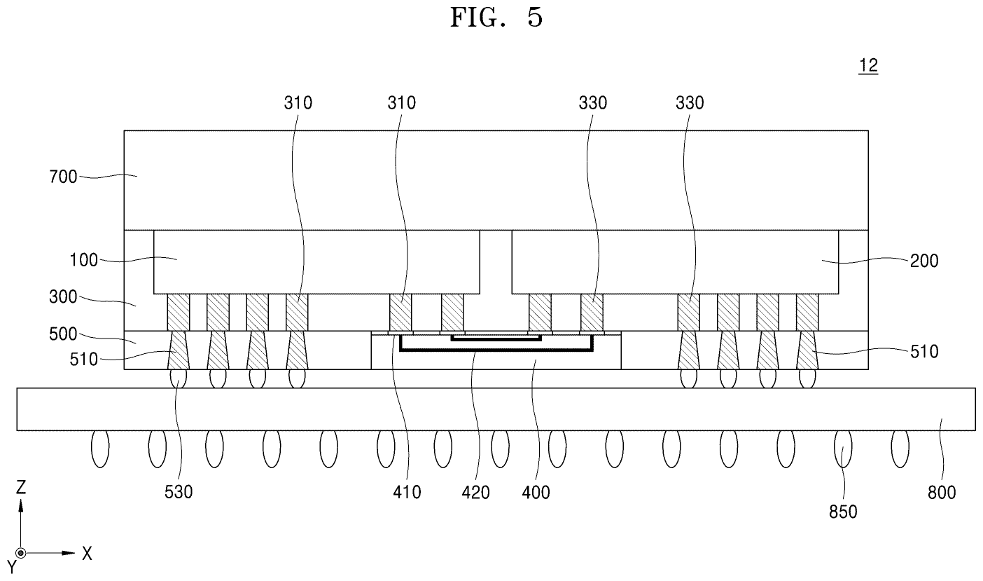

FIG. 5 is a schematic cross-sectional view of a semiconductor package 12 according to an embodiment. Hereinafter, in the description of the semiconductor package 12 of FIG. 5, descriptions identical to descriptions about the semiconductor package 10 given above with reference to FIGS. 1 and 2 may be omitted.

Referring to FIG. 5, the semiconductor package 12 may include a first semiconductor chip 100, a second semiconductor chip 200, a first dielectric film 300, a plurality of first via 310, a plurality of second via 330, a bridge chip 400, a second dielectric film 500, a plurality of third via 510, a second carrier substrate 700, external connection terminals 850, and a first substrate 800.

The first substrate 800 may be positioned below the second dielectric film 500 and electrically connected to the plurality of the third vias 510 formed inside the second dielectric film 500 through the first bumps 530. The first substrate 800 may be formed based on or include, for example, a ceramic substrate, a printed circuit board (PCB), an organic substrate, or the like. In some embodiments, the first substrate 800 may be a redistribution substrate formed through a redistribution process.

The external connection terminals 850 may be located on at least one pad disposed on a lower surface of the first substrate 800. The external connection terminals 850 may be electrically connected to the at least one pad. The external connection terminals 850 may be electrically connected to wiring patterns formed inside the first substrate 800 through the at least one pad. The external connection terminals 850 may be electrically connected to an external device, for example, a motherboard. Accordingly, the semiconductor package 12 may be electrically connected to an external device through the external connection terminals 850.

The external connection terminals 850 may include a solder ball. However, according to embodiments, the external connection terminals 850 may have a structure including a pillar and a solder. The external connection terminals 850 may include at least one from among copper (Cu), silver (Ag), gold (Au), and tin (Sb).

According to some embodiments, the first semiconductor chip 100 and the second semiconductor chip 200 may be different types of chips. For example, the first semiconductor chip 100 may be a memory chip and the second semiconductor chip may be a logic chip. In some embodiments, the first semiconductor chip 100 may include a high bandwidth memory (HBM) DRAM chip. In this case, the first semiconductor chip 100 may be a chip stack structure in which HBM DRAM chips are stacked in the vertical direction Z.

When the semiconductor package 12 further includes a first substrate 800 and the first semiconductor chip 100 and the second semiconductor chip 200 include different types of chips, the semiconductor package 12 may be understood as a 2.3D package. The 2.3D package may be understood as a package in which heterogeneous semiconductor chips, that is, the first semiconductor chip 100 and the second semiconductor chip 200, are spaced apart from each other in the horizontal direction and the bridge chip 400 electrically connects the first semiconductor chip 100 to the second semiconductor chip 200 instead of an interposer substrate.

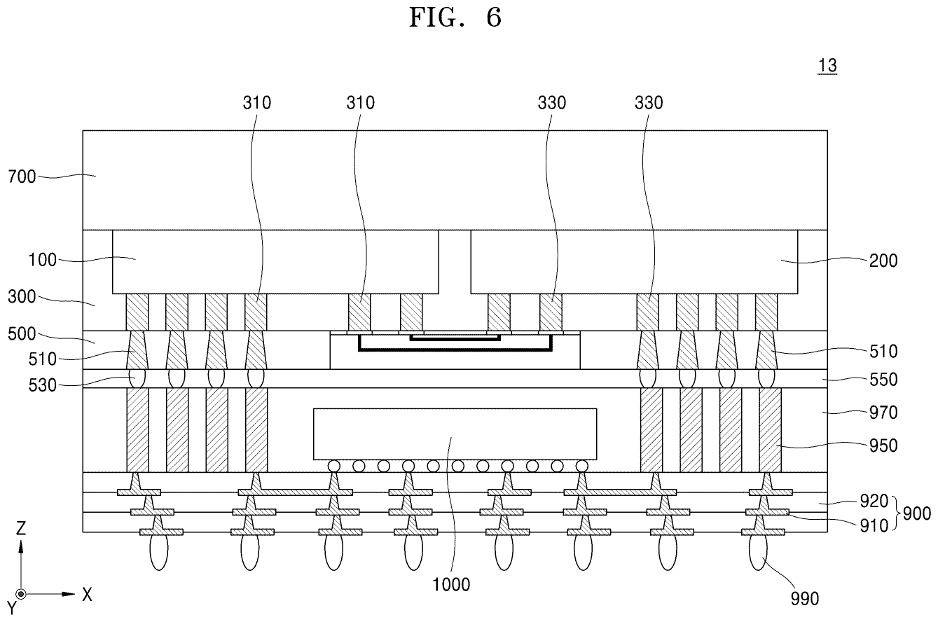

FIG. 6 is a schematic cross-sectional view of a semiconductor package 13 according to an embodiment. Hereinafter, in the description of the semiconductor package 13 of FIG. 6, descriptions identical to descriptions about the semiconductor package 10 given above with reference to FIGS. 1 and 2 may be omitted.

Referring to FIG. 6, the semiconductor package 13 may include a first semiconductor chip 100, a second semiconductor chip 200, a first dielectric film 300, a plurality of first via 310, a plurality of second via 330, a bridge chip 400, the second dielectric film 500, a plurality of third via 510, a second carrier substrate 700, a second substrate 900, a third semiconductor chip 1000, conductive pillars 950, an adhesive layer 550, and a molding member 970.

The adhesive layer 550 may be configured to surround the first bumps 530 and to fix the molding member 970 and the second dielectric film 500. The adhesive layer 550 may include, for example, a nonconductive film (NCF) or an underfill material layer.

The conductive pillars 950 may be positioned below the second dielectric film 550 and electrically connected to the first bumps 530. The conductive pillars 950 may have a shape extending in the vertical direction Z. The conductive pillars 950 may pass through the molding member 970 and extend in the vertical direction Z. The conductive pillars 950 may be, for example, through mold vias or conductive posts. The conductive pillars 950 may include, for example, copper (Cu). The conductive pillars 950 may electrically connect redistribution patterns 910 to the first bumps 530.

The third semiconductor chip 1000 may be mounted on the second substrate 900 and may be spaced apart from the conductive pillars 950 in the horizontal direction. The third semiconductor chip 1000 may be a memory chip or a logic chip. In some embodiments, the third semiconductor chip 1000 may be an application specific integrated circuit (ASIC) chip.

The molding member 970 may surround the third semiconductor chip 1000 and the conductive pillars 950. The molding member 970 may include a thermosetting resin such as epoxy resin, a thermoplastic resin such as polyimide, or a resin containing a reinforcing material such as an inorganic filler, specifically ajinomoto build-up film (ABF), FR-4, BT, and the like, but the molding member 970 may be formed from a molding material such as an epoxy molding compound (EMC) or a photosensitive material such as photo imageable encapsulant (PIE). In some embodiments, a portion of the molding member 970 may include an insulating material such as a silicon oxide film, a silicon nitride film, or a silicon oxynitride film.

The second substrate 900 may be positioned below the molding member 970 and may be electrically connected to the conductive pillars 950 and the third semiconductor chip 1000. The second substrate 900 may be formed based on or include a ceramic substrate, a PCB, an organic substrate, or the like but is not limited thereto. For example, the second substrate 900 may be a redistribution substrate formed through a redistribution process. Hereinafter, it is assumed and described that the second substrate 900 is a redistribution substrate formed through a redistribution process.

The second substrate 900 may include redistribution insulating layers 920 and the redistribution patterns 910. The second substrate 900 may include the redistribution insulating layers 920 mutually stacked in the vertical direction Z. The redistribution insulating layers 920 may include, for example, photo imageable dielectric (PID) or photosensitive polyimide (PSPI).

The redistribution patterns 910 may be provided in the redistribution insulating layers 920. The redistribution patterns 910 may be formed to penetrate the redistribution insulating layers 920 from an upper surface to a lower surface of the second substrate 900. Accordingly, the redistribution patterns 910 may serve as an electrical connection passage penetrating the upper and lower surfaces of the second substrate 900. That is, the third semiconductor chip 1000 positioned on the upper surface of the second substrate 900 and external connection terminals 990 positioned on the lower surface of the second substrate 900 may be electrically connected. In addition, the redistribution patterns 910 may electrically connect the conductive pillars 950 to the third semiconductor chip 1000 and electrically connect the conductive pillars 950 to the external connection terminals 990.

The redistribution pattern 910 may include a metal, for example, copper (Cu), aluminum (Al), tungsten (W), titanium (Ti), tantalum (Ta), indium (In), molybdenum (Mo), manganese (Mn), cobalt (Co), tin (Sn), nickel (Ni), magnesium (Mg), rhenium (Re), beryllium (Be), gallium (Ga), ruthenium (Ru), etc. or an alloy of metals, but the redistribution pattern 910 is not limited thereto. In some embodiments, the redistribution patterns 910 may be formed by depositing a metal or a metal alloy on a seed layer including copper (Cu), titanium (Ti), titanium nitride (TiN), or titanium tungsten (TiW).

The redistribution patterns 910 may include a redistribution line pattern and a redistribution via pattern. The redistribution patterns 910 may have a multilayer structure in which redistribution line patterns and redistribution via patterns are alternately stacked.

The redistribution line patterns may have a shape extending in the horizontal direction along at least one of upper and lower surfaces of each of the redistribution insulating layers 920. The redistribution via patterns may have a shape extending through the redistribution insulating layers 920 in the vertical direction Z. The redistribution via patterns may electrically connect redistribution line patterns located at different levels in the vertical direction Z. In some embodiments, at least some of the redistribution line patterns may be integrally formed with some of the redistribution via patterns.

The semiconductor package 13 may be a package on package type semiconductor package because the semiconductor package 13 further includes the conductive pillars 950, the molding member 970, the third semiconductor chip 1000, the second substrate 900, etc.

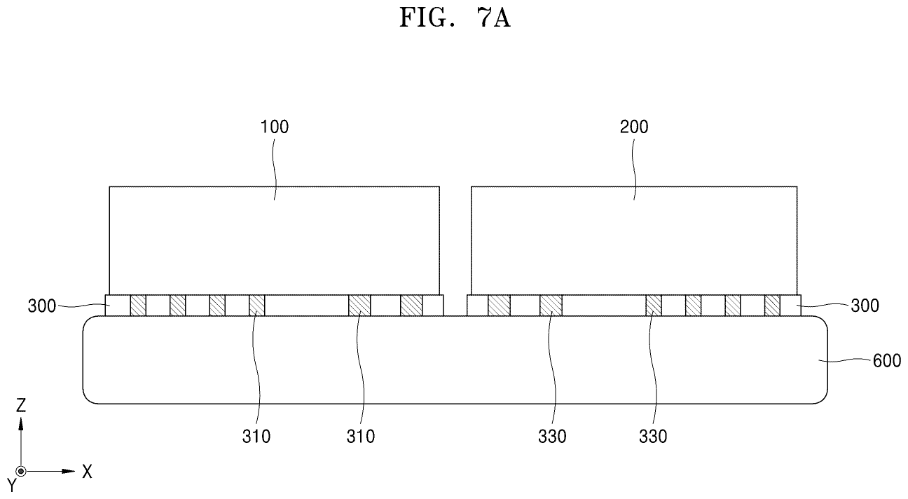

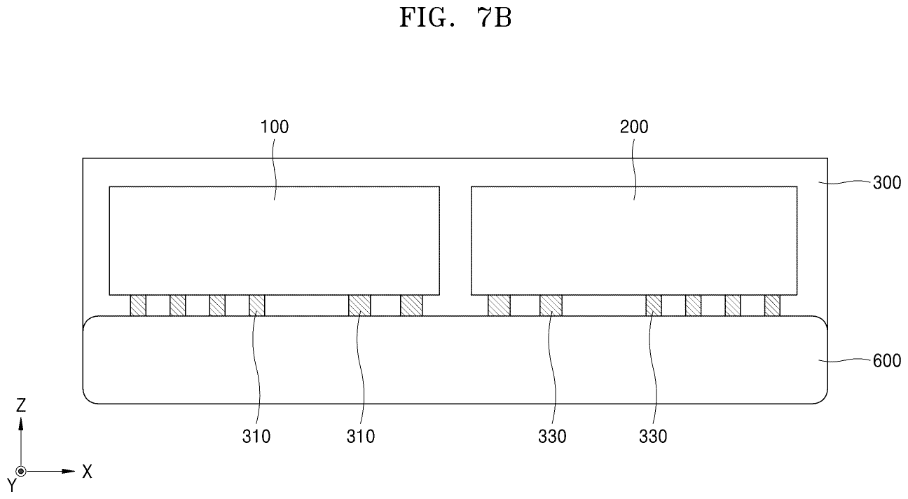

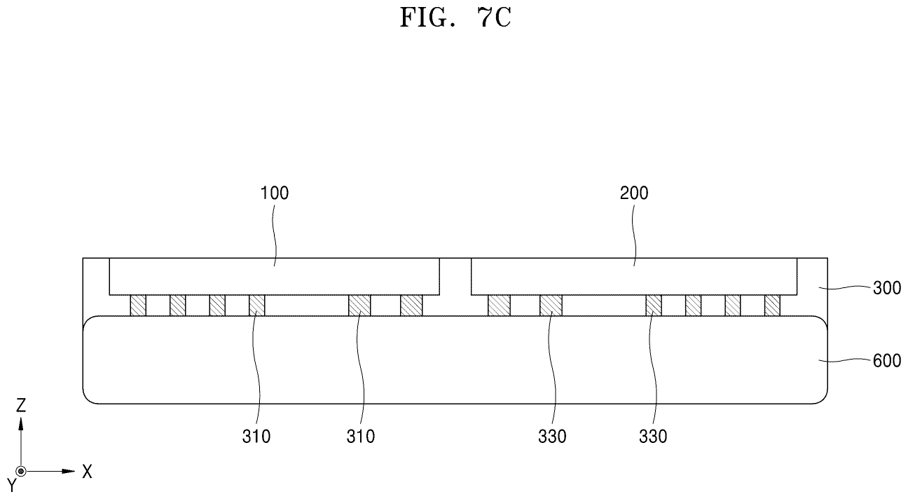

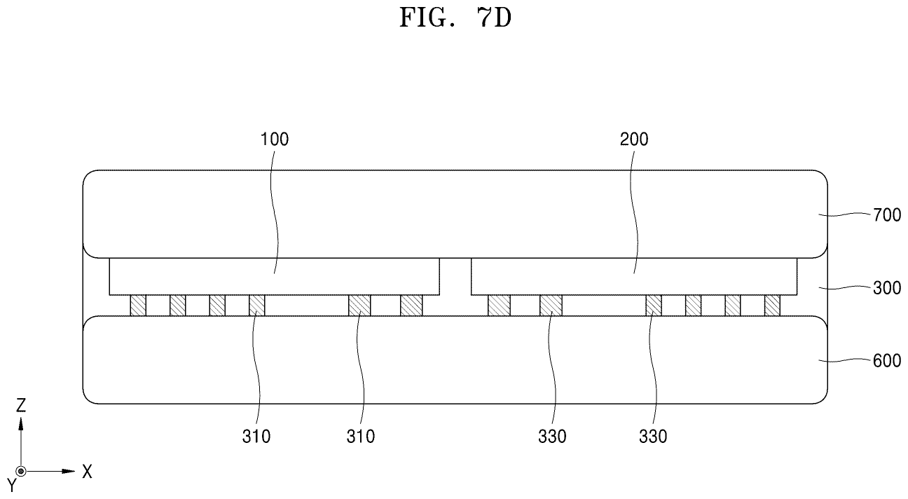

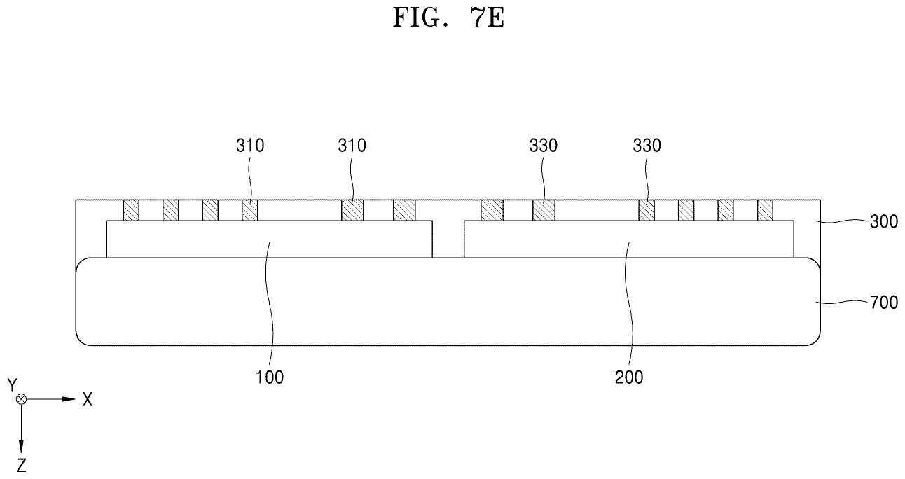

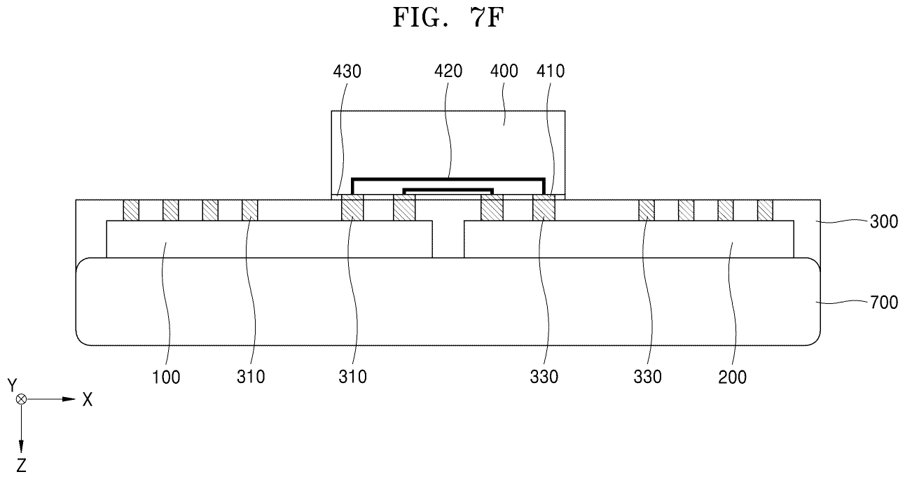

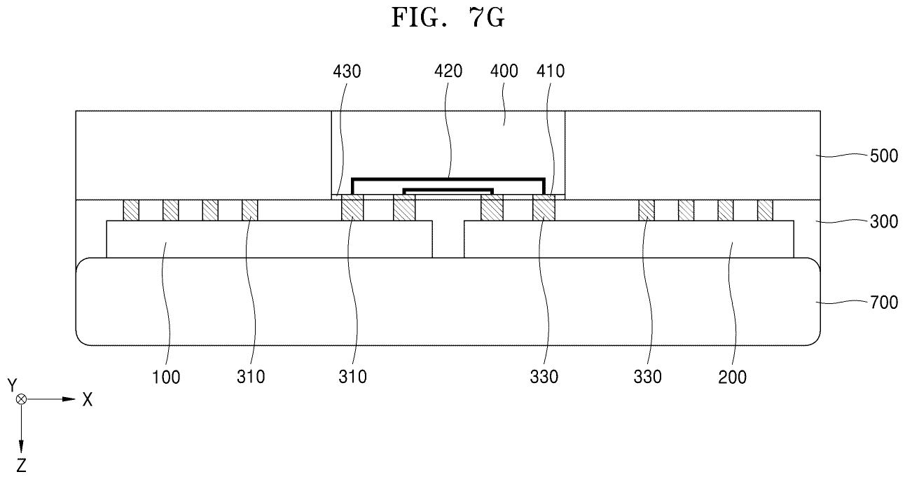

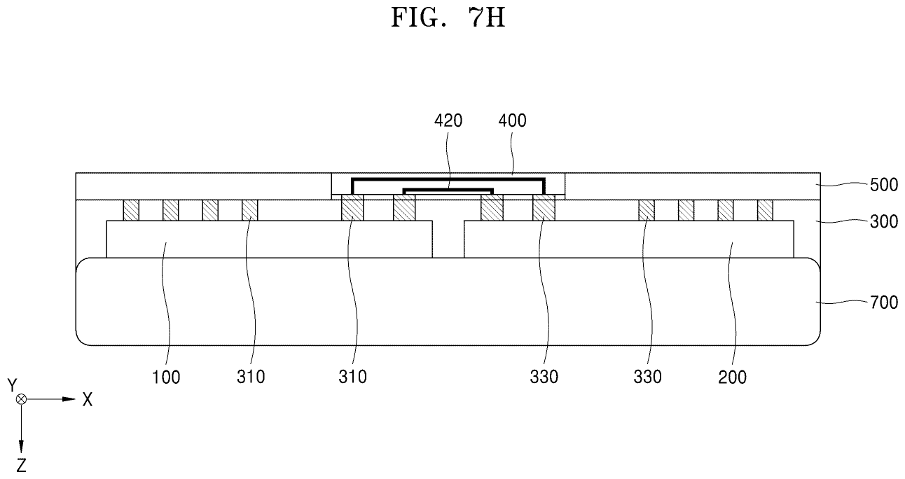

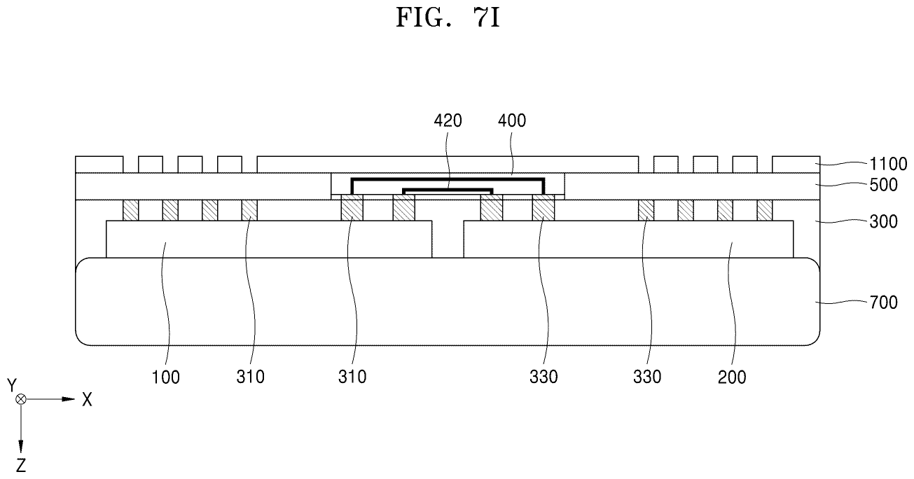

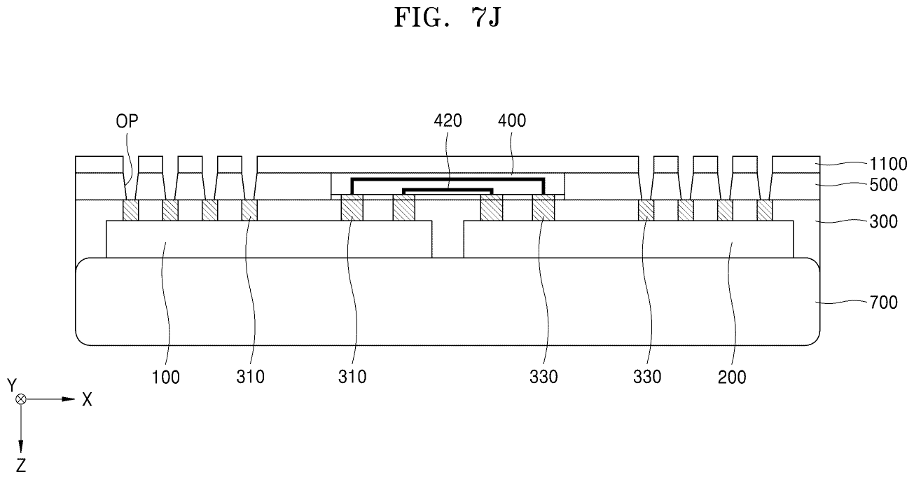

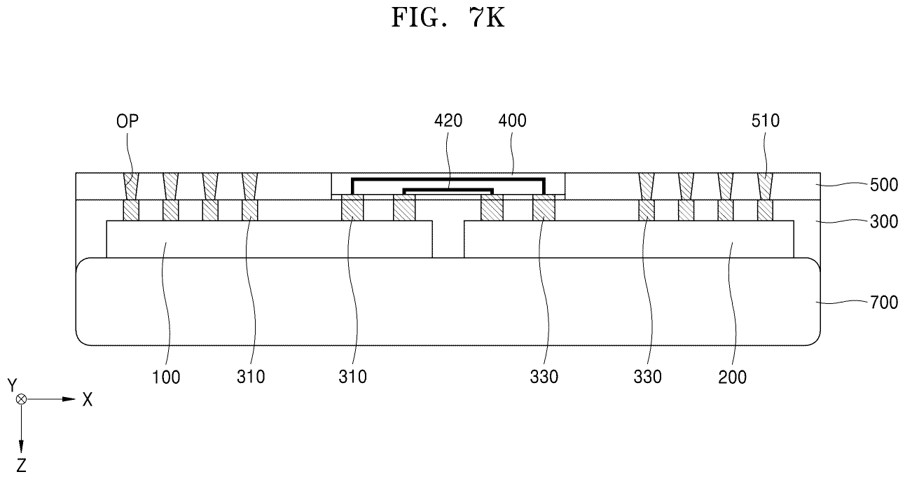

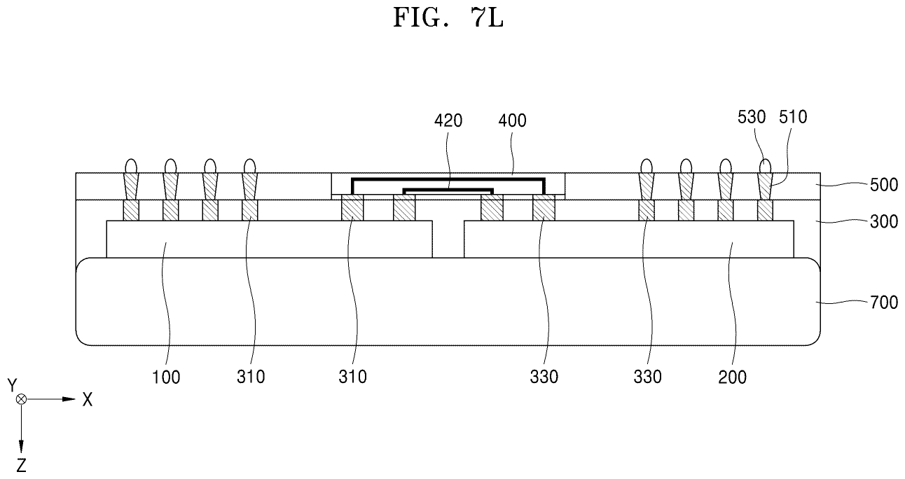

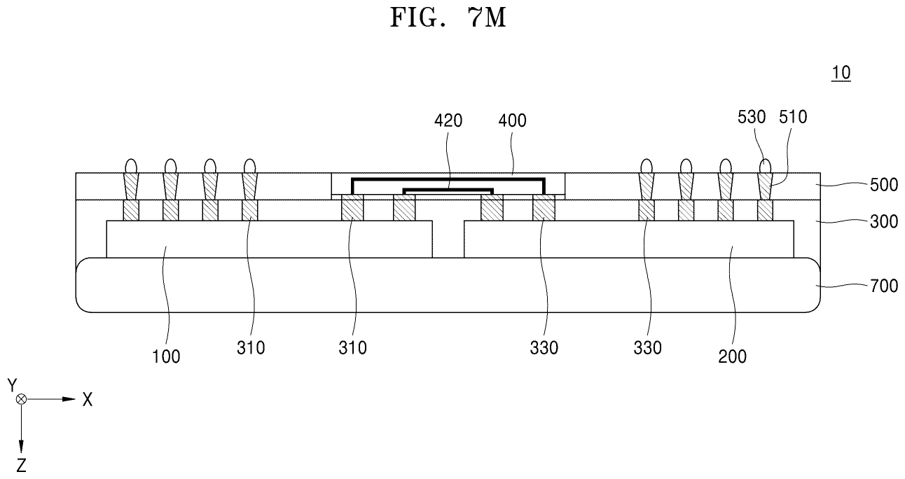

FIGS. 7A to 7M are cross-sectional views illustrating a method of manufacturing the semiconductor package 10, according to an embodiment. Hereinafter, a method of manufacturing the semiconductor package 10 will be described with reference to FIGS. 7A to 7M.

Referring to FIG. 7A, the first semiconductor chip 100 and the second semiconductor chip 200 are provided on a first carrier substrate 600. The first dielectric film 300 and the plurality of the first vias 310 passing through the first dielectric film 300 may be positioned between the first carrier substrate 600 and the first semiconductor chip 100, and the first dielectric film 300 and the plurality of the second vias 330 may be positioned between the first carrier substrate 600 and the second semiconductor chip 200. According to some embodiments, each of the first dielectric films 300 provided under each of the first semiconductor chip 100 and the second semiconductor chip 200 may be spaced apart from each other in the first horizontal direction X.

Referring to FIG. 7B, the first dielectric film 300 may be deposited by coating a dielectric material on the upper surface of the first carrier substrate 600. In some embodiments, an upper surface of the first dielectric film 300 may be substantially at the same level as or higher than the upper surfaces of the first semiconductor chip 100 and the second semiconductor chip 200 in the vertical direction Z.

Referring to FIG. 7C, thicknesses of the first semiconductor chip 100, the second semiconductor chip 200, and the first dielectric film 300 in the vertical direction Z are reduced. For example, the thicknesses of the first semiconductor chip 100, the second semiconductor chip 200, and the first dielectric film 300 in the vertical direction Z may be adjusted through a grinding process or a chemical mechanical polishing (CMP) process.

Referring to FIGS. 7D and 7E, after adjusting the thicknesses of the first semiconductor chip 100, the second semiconductor chip 200, and the first dielectric film 300 in the vertical direction Z, the second carrier substrate 700 is attached such that the second carrier substrate 700 contacts the upper surface of each of the second semiconductor chip 200 and the third semiconductor chip 1000. The second carrier substrate 700 may be coupled to upper surfaces of the first semiconductor chip 100, the second semiconductor chip 200, and the first dielectric film 300 through direct bonding. After the second carrier substrate 700 is coupled to the upper surfaces of the first semiconductor chip 100, the second semiconductor chip 200, and the first dielectric film 300, as shown in FIG. 7E, the resultant product is turned over so that the second carrier substrate 700 is located at the bottom. After that, the first carrier substrate 600 is removed from the first semiconductor chip 100 and the second semiconductor chip 200.

Hereinafter, an upper surface and a lower surface are defined based on FIG. 7E. For example, a surface referred to as a lower surface in FIGS. 7A and 7D may be understood as an upper surface in FIG. 7E and below.

Referring to FIG. 7F, after the first carrier substrate 600 is removed, the bridge chip 400 may be mounted on the upper surfaces of the first semiconductor chip 100 and the second semiconductor chip 200. According to some embodiments, the bridge chip 400 may be connected to the first semiconductor chip 100 and the second semiconductor chip 200 through hybrid bonding. In this case, the passivation layer 430 of the bridge chip 400 may include the same material as a material of the first dielectric film 300, the bridge chip pads 410 connected to the plurality of the first vias 310 may include the same material as the plurality of the first vias 310, and the bridge chip pads 410 connected to the plurality of the second vias 330 may include the same material as a material of the plurality of the second vias 330. Accordingly, the bridge chip 400 may be coupled to the first semiconductor chip 100 and the second semiconductor chip 200 through hybrid bonding in which dielectric-dielectric bonding and metal-metal bonding occur together.

Referring to FIGS. 7G and 7H, the second dielectric film 500 is formed on the first dielectric film 300 to cover the bridge chip 400. The second dielectric film 500 may be formed to cover the upper surface of the bridge chip 400 or only cover side surfaces of the bridge chip 400. The second dielectric film 500 may include the same material as a material of the first dielectric film 300 but is not limited thereto. For example, the second dielectric film 500 may include a different material from a material of the first dielectric film 300. After forming the second dielectric film 500, the thicknesses of the second dielectric film 500 and the bridge chip 400 in the vertical direction Z may be reduced through a grinding process or a CMP process.

Referring to FIGS. 71 and 7J, a photoresist layer 1100 is formed on the upper surface of the second dielectric film 500. The photoresist layer 1100 may include a pattern formed through an exposure process and a development process. After forming the photoresist layer 1100, openings OP may be formed in the second dielectric film 500 through an etching process. In this case, the photoresist layer 1100 may act as a hard mask. The openings OP may extend from the upper surface to the lower surface of the second dielectric film 500, and the upper surfaces of the plurality of the first vias 310 and the upper surfaces of the plurality of the second vias 330 may be exposed upward in the vertical direction Z by the openings OP. According to some embodiments, the openings OP may have a shape in which a horizontal width decreases as a level in the vertical direction Z decreases.

Referring to FIGS. 7K and 7L, the plurality of the third vis 510 may be formed by filling the openings OP formed in the second dielectric film 500 with a metal material. The plurality of the third vias 510 may have a shape in which a horizontal width decreases as the level in the vertical direction Z decreases. The plurality of the third vias 510 may have substantially the same thickness as a thickness of the bridge chip 400 in the vertical direction Z. After forming the plurality of the third vias 510, the first bumps 530 are formed on the upper surface of the third vias 510.

Referring to FIG. 7M, after forming the first bumps 530, the thickness of the second carrier substrate 700 in the vertical direction Z is adjusted. The thickness of the second carrier substrate 700 in the vertical direction Z may be reduced through a grinding process or a CMP process. Because the second carrier substrate 700 includes silicon, the thickness of the second carrier substrate 700 in the vertical direction Z may be adjusted without a separate limitation. The second carrier substrate 700 is not finally removed and may function as a heat dissipation member that discharges heat generated inside the semiconductor package 10 to the outside.

While non-limiting example embodiments of the present disclosure have been particularly shown and described, it will be understood that various changes in form and details may be made therein without departing from the spirit and scope of the present disclosure.

What is claimed is:

1. A semiconductor package comprising:
a first semiconductor chip;
a second semiconductor chip spaced apart from the first semiconductor chip in a horizontal direction;
a first dielectric film surrounding the first semiconductor chip and the second semiconductor chip;
first vias extending from a lower surface of the first dielectric film to a lower surface of the first semiconductor chip;
second vias extending from the lower surface of the first dielectric film to a lower surface of the second semiconductor chip;
a bridge chip on the lower surface of the first dielectric film and electrically connected to each of the first semiconductor chip and the second semiconductor chip, the bridge chip comprising bridge chip pads and a passivation layer surrounding the bridge chip pads;
a second dielectric film surrounding the bridge chip and having an upper surface and a lower surface opposite to the upper surface of the second dielectric film; and
third vias extending from the lower surface of the second dielectric film to the upper surface of the second dielectric film,
wherein a first set of the first vias is electrically connected to a first set of the bridge chip pads,
wherein a first set of the second vias is electrically connected to a second set of the bridge chip pads, and
wherein the passivation layer comprises a same material as a material of the first dielectric film.

2. The semiconductor package of claim 1, wherein each of the first dielectric film and the second dielectric film comprises one from among a silicon oxide film and a silicon nitride film.

3. The semiconductor package of claim 1, further comprising a carrier substrate on an upper surface of the first semiconductor chip, an upper surface of the second semiconductor chip, and an upper surface of the first dielectric film.

4. The semiconductor package of claim 3, further comprising:
at least one third dielectric film on the upper surface of the first semiconductor chip and the upper surface of the second semiconductor chip; and
a fourth dielectric film on a lower surface of the carrier substrate,
wherein the at least one third dielectric film and the fourth dielectric film comprise a same material as the material of the first dielectric film.

5. The semiconductor package of claim 1, wherein the third vias have a tapered shape in which a horizontal width increases as a vertical level decreases.

6. The semiconductor package of claim 1, further comprising:
a first bump on the lower surface of the second dielectric film and electrically connected to one of the third vias; and
a first substrate under the second dielectric film and electrically connected to the first bump,
wherein the first semiconductor chip is a memory chip, and the second semiconductor chip is a logic chip.

7. The semiconductor package of claim 1, further comprising:
a first bump on the lower surface of the second dielectric film and electrically connected to one of the third vias;
a conductive pillar electrically connected to the first bump and extending in a vertical direction;
a third semiconductor chip separated from the conductive pillar in the horizontal direction;
a molding member surrounding the conductive pillar and the third semiconductor chip, and
a second substrate below the molding member.

8. The semiconductor package of claim 1, wherein the lower surface of the first semiconductor chip is at a lower vertical level than a vertical level of the lower surface of the second semiconductor chip.

9. The semiconductor package of claim 1, wherein
lower surfaces of the first set of the first vias and upper surfaces of the first set of the bridge chip pads are in contact with each other, and
lower surfaces of the first set of the second vias and upper surfaces of the second set of the bridge chip pads are in contact with each other.

10. The semiconductor package of claim 9, wherein
the first set of the first vias and the first set of the bridge chip pads comprise a same material as each other, and
the first set of the second vias and the second set of the bridge chip pads comprise a same material as each other.

11. A semiconductor package comprising:
a first semiconductor chip;
a second semiconductor chip spaced apart from the first semiconductor chip in a horizontal direction;
a first dielectric film surrounding the first semiconductor chip and the second semiconductor chip;
a carrier substrate that contacts an upper surface of the first semiconductor chip, an upper surface of the second semiconductor chip, and an upper surface of the first dielectric film;
first vias extending from a lower surface of the first dielectric film to a lower surface of the first semiconductor chip;
second vias extending from the lower surface of the first dielectric film to a lower surface of the second semiconductor chip;
a bridge chip on the lower surface of the first dielectric film and electrically connected to each of the first semiconductor chip and the second semiconductor chip, the bridge chip comprising bridge chip pads and a passivation layer surrounding the bridge chip pads;
a second dielectric film surrounding the bridge chip and having an upper surface and a lower surface opposite to the upper surface of the second dielectric film; and
third vias extending from the lower surface of the second dielectric film to the upper surface of the second dielectric film,
wherein a first set of the first vias is electrically connected to a first set of the bridge chip pads,
wherein a first set of the second vias is electrically connected to a second set of the bridge chip pads, and
wherein the passivation layer comprises a same material as a material of the first dielectric film, the first set of the first vias and the first set of the bridge chip pads comprise a same material as each other, and the first set of the second vias and the second set of the bridge chip pads comprise a same material as each other.

12. The semiconductor package of claim 11, wherein each of the first dielectric film and the second dielectric film comprises one from among a silicon oxide film and a silicon nitride film.

13. The semiconductor package of claim 12, wherein the first dielectric film and the second dielectric film comprise different materials from each other.

14. The semiconductor package of claim 11, further comprising:
at least one third dielectric film on the upper surface of the first semiconductor chip and the upper surface of the second semiconductor chip; and
a fourth dielectric film on a lower surface of the carrier substrate,
wherein the at least one third dielectric film and the fourth dielectric film comprise a same material as the material of the first dielectric film.

15. The semiconductor package of claim 11, wherein a length of the first semiconductor chip in the horizontal direction is less than a length of the second semiconductor chip in the horizontal direction.

16. The semiconductor package of claim 11, wherein
lower surfaces of the first set of the first vias and upper surfaces of the first set of the bridge chip pads are in contact with each other without a separate bump therebetween, and
lower surfaces of the first set of the second vias and upper surfaces of the second set of the bridge chip pads are in contact with each other without a separate bump therebetween.

17. The semiconductor package of claim 11, wherein the third vias have a tapered shape in which a horizontal width increases as a vertical level decreases.

18. A semiconductor package comprising:
a first semiconductor chip;
a second semiconductor chip spaced apart from the first semiconductor chip in a horizontal direction;
a first dielectric film surrounding the first semiconductor chip and the second semiconductor chip;
at least one third dielectric film on a upper surface of the first semiconductor chip and an upper surface of the second semiconductor chip;
a carrier substrate comprising a fourth dielectric film that contacts an upper surface of the at least one third dielectric film and an upper surface of the first dielectric film;
first vias extending from a lower surface of the first dielectric film to a lower surface of the first semiconductor chip;
second vias extending from the lower surface of the first dielectric film to a lower surface of the second semiconductor chip;
a bridge chip on the lower surface of the first dielectric film and electrically connected to each of the first semiconductor chip and the second semiconductor chip, the bridge chip comprising bridge chip pads and a passivation layer surrounding the bridge chip pads;
a second dielectric film surrounding the bridge chip and having an upper surface and a lower surface opposite to the upper surface of the second dielectric film;
third vias extending from the lower surface of the second dielectric film to the upper surface of the second dielectric film, and
a first bump on the lower surface of the second dielectric film and electrically connected to one of the third vias,
wherein a first set of the first vias is electrically connected to a first set of the bridge chip pads,
wherein a first set of the second vias is electrically connected to a second set of the bridge chip pads,
wherein the passivation layer comprises a same material as a material of the first dielectric film, the first set of the first vias and the first set of the bridge chip pads comprise a same material as each other, and the first set of the second vias and the second set of the bridge chip pads comprise a same material as each other, and
wherein lower surfaces of the first set of the first vias and upper surfaces of the first set of the bridge chip pads are in contact with each other, lower surfaces of the first set of the second vias and upper surfaces of the second set of the bridge chip pads are in contact with each other, and each of the first dielectric film and the second dielectric film comprises one from among a silicon oxide film and a silicon nitride film.

19. The semiconductor package of claim 18, further comprising a first substrate below the second dielectric film and electrically connected to the first bump,
wherein the first semiconductor chip is a memory chip, and the second semiconductor chip is a logic chip.

20. The semiconductor package of claim 18, further comprising:
a conductive pillar electrically connected to the first bump and extending in a vertical direction;
a third semiconductor chip separated from the conductive pillar in the horizontal direction;
a molding member that surrounds the conductive pillar and the third semiconductor chip, and
a second substrate under the molding member.
